(19) United States
(12) Patent Application Publication
(10) Pub. No.: US 2014/0087586 A1
(43) Pub. Date: Mar. 27, 2014

(54) SECURING OPPOSING COMPONENTS TO A CIRCUIT BOARD

(71) Applicant: INTERNATIONAL BUSINESS MACHINES CORPORATION, Armonk, NY (US)

(72) Inventors: Kevin M. O'Connell, Rochester, MN (US); Arvind K. Sinha, Rochester, MN (US); Kory W. Weckman, Rochester, MN (US)

(73) Assignee: International Business Machines Corporation, Armonk, NY (US)

(21) Appl. No.: 13/626,658

(22) Filed: Sep. 25, 2012

(51) Int. Cl. H01R 13/73; H05K 3/30; H05K 7/02

(52) U.S. Cl. 439/527; 361/809; 29/832

(57) ABSTRACT

According to embodiments of the invention, an assembly having first and second components may be provided. The first component may include one or more connectors corresponding to one or more through-holes of a circuit board. The second component may include one or more receptacles to fixedly receive the connectors, wherein the first and second components are adapted to be located on opposing sides of the circuit board in an assembled position. In some embodiments, the first and second components may include electrical connectors soldered to the circuit board. In some embodiments, the connectors may include one or more pawls and the receptacles may include one or more ratchets. In other embodiments, the connectors may be threaded members and the receptacles may be threaded apertures.

### TECHNICAL FIELD

The field of the invention relates generally to electronic components, and more specifically, to securing opposing electronic components to a circuit board.

### BACKGROUND

Computer systems typically include a combination of computer programs and hardware, such as semiconductors, transistors, chips, circuit boards, storage devices, and processors. The computer programs are stored in the storage devices and are executed by the processors. A common feature of many computer systems is the presence of one or more circuit boards. Circuit boards contain a variety of components mounted to a board.

### SUMMARY

According to embodiments of the invention, an assembly having first and second components may be provided. The first component may include one or more connectors corresponding to one or more through-holes of a circuit board. The second component may include one or more receptacles to fixedly receive the connectors, wherein the first and second components are adapted to be located on opposing sides of the circuit board in an assembled position. In some embodiments, the first and second components may include electrical connectors soldered to the circuit board. In some embodiments, the connectors may include one or more pawls and the receptacles may include one or more ratchets. In other embodiments, the connectors may be threaded members and the receptacles may be threaded apertures.

According to other embodiments, a method may be provided for securing opposing components to a circuit board. The method may include an operation of placing a first component having one or more connectors on a first side of a circuit board having one or more through-holes corresponding to the connectors. The method may also include an operation of placing a second component having one or more receptacles to fixedly receive the connectors on a second side of the circuit board, wherein the first side of the circuit board and the second side of the circuit board are opposing sides. In other embodiments, the method may also include an operation of soldering electrical connectors located on the first and second components to electrical connectors located on the circuit board.

### BRIEF DESCRIPTION OF THE SEVERAL VIEWS OF THE DRAWINGS

FIG. 1A is a top view of an assembly, according to an embodiment of the invention.

FIG. 1B is a bottom view of the assembly, according to an embodiment of the invention.

FIG. 2A is a side view of the assembly in an exploded position, according to an embodiment of the invention.

FIG. 2B is a side view of an assembly in an assembled position with a partial cross-section, according to an embodiment of the invention.

FIG. 2C is a zoomed view of area 206 of FIG. 2B, according to an embodiment of the invention.

FIG. 2D is an alternative embodiment of FIG. 2C.

FIG. 2E is a top view of a connector, according to an embodiment of the invention.

FIG. 2F is a top view of a receptacle, according to an embodiment of the invention.

FIG. 3 is a flow chart of a method of securing opposing components to a circuit board, according to an embodiment of the invention.

In the drawings and the Detailed Description, like numbers generally refer to like components, parts, steps, and processes.

### DETAILED DESCRIPTION

The growing demand for computer systems to have increased capabilities in ever smaller sizes motivates the creation of new ways to assemble the large quantity of components that make up a computer system. These new ways of assembly require designing computer systems that fit into a smaller area but at the same time maintaining or improving functionality and allowing the system to operate at a safe temperature. Dual or single in-line memory modules (DIMMs or SIMMs) are examples of component that due to the ever increasing number of memory modules present in modern computer systems, create an ever increasing need to assemble the memory modules is smaller spaces while maintaining cooling performance of the modules. Traditionally, memory modules, along with most other components, were mounted on a single side of a circuit board, however, an assembly that utilizes both sides of the circuit board provides designers with more options to create designs that may increase the number of components within a given computer system.

Another issue may arise when mounting in-line memory module connectors with multiple electrical connections to a single side of a circuit board. The connectors may have a large number of electrical connectors, such as those used in surface-mount technology (SMT). When these connectors are soldered to a circuit board there is the potential for the circuit board, the connectors, or both to warp due to heating. Embodiments of the invention provide a system for securing two components to opposing sides of a circuit board that provide more options to mount a greater number of components to the circuit board while also providing resistance to any tendency the circuit board or the components may have to warp due to heat. Embodiments of the invention accomplish this by utilizing two in-line memory module connectors mounted on opposing sides of a circuit board. The connectors may include complimenting connectors that pass through holes in the circuit board and connect to each other to secure the connectors to the board. This configuration functions as a type of clamping assembly that secures the connectors to the circuit board. In some embodiments this configuration may have a tendency to resist warping due to heat.

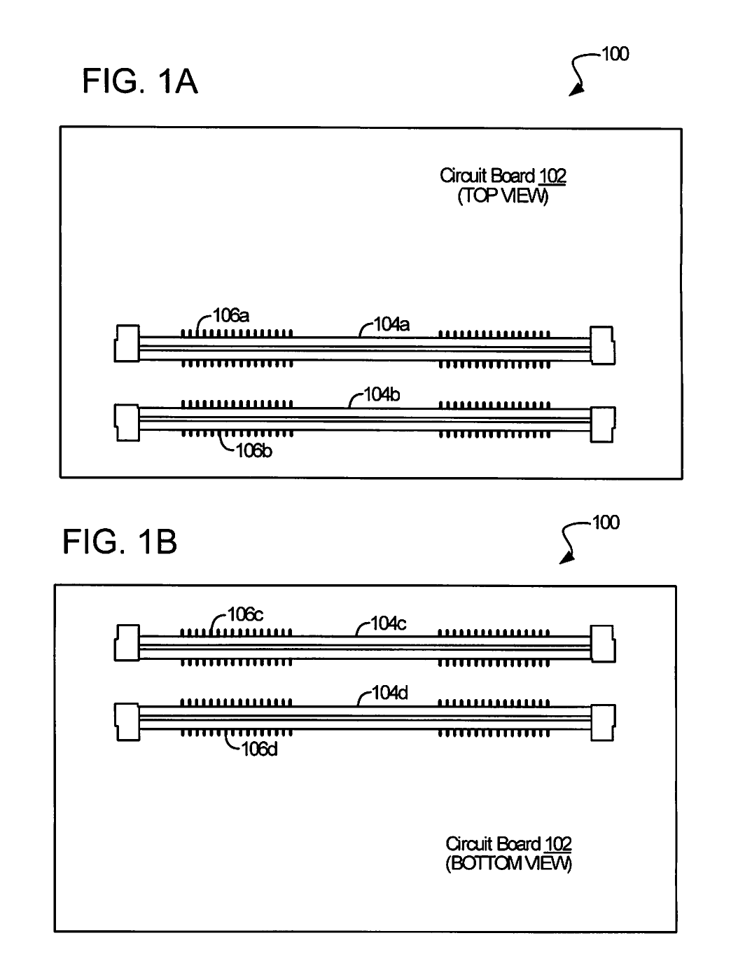

Referring to the drawings, wherein like numbers denote like parts throughout the several views, FIG. 1A depicts the top view of an assembly 100, according to an embodiment of the invention. The assembly 100 may be an element of a computer system such as a mainframe, server, or personal computer. For example, the assembly 100 may be a motherboard. The assembly 100 may include a circuit board 102 and one or more components 104a and 104b, such as connectors for in-line memory modules. The components 104a and 104b may include any number of electrical connectors 106a and 106b, respectively, in a position to facilitate an electrical connection, such as SMT, to the circuit board 102 when the components 104a and 104b are mounted to the circuit board 102.

FIG. 1B is a bottom view of the assembly 100, according to an embodiment of the invention. Along with the components of FIG. 1A mentioned above, the assembly 100 may also include one or more components 104c and 104d, which may also be connectors for in-line memory modules. Like components 104a and 104b, the components 104c and 104d may include any number of electrical connectors 160c and 106d in a position to facilitate an electrical connection, such as SMT, to the circuit board 102 when the components 104c and 104d are mounted to the circuit board 102. The component 104c may be mounted to the circuit board 102 opposite the component 104b and the component 104d may be mounted to the circuit board 102 opposite the component 104a.

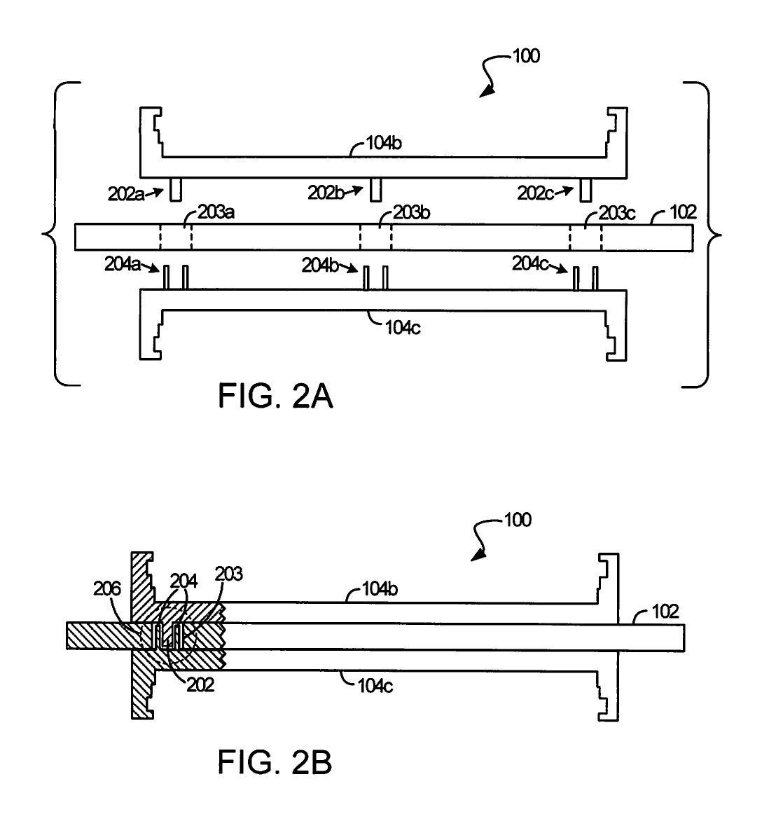

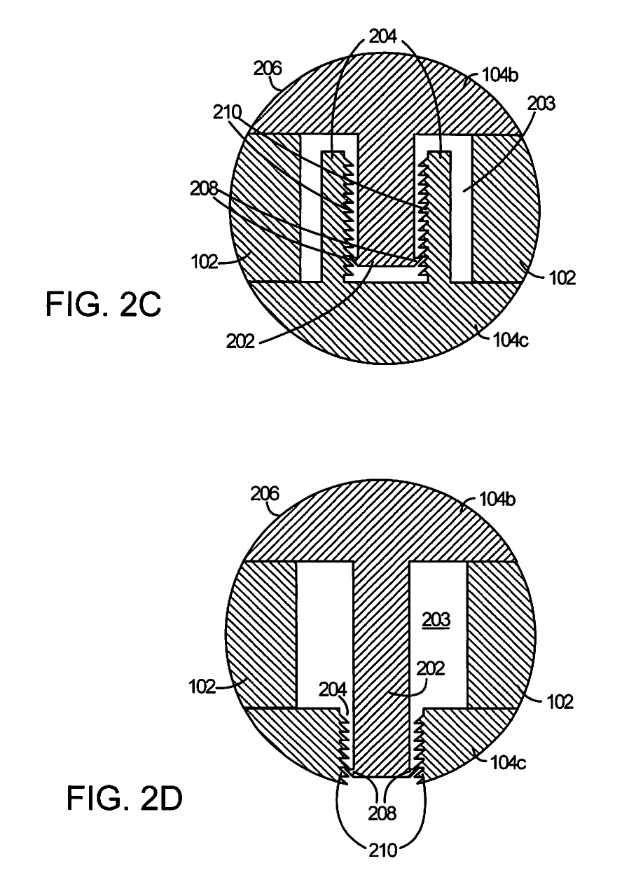

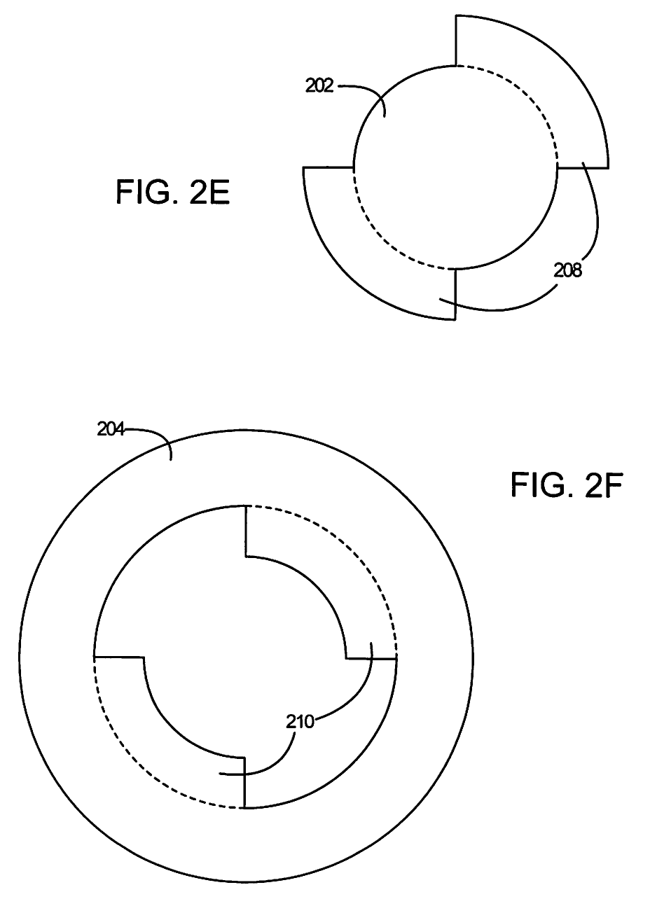

FIG. 2A is a side view of the assembly 100 in an exploded position, according to an embodiment of the invention. The component 104b may include connectors 202a, 202b and 202c located on a surface of the component 104b facing the circuit board 102. The connectors 202 may correspond to through-holes 203a, 203b and 203c of the circuit board 102. The component 104c may include receptacles 204a, 204b, and 204c located on a surface of the component 104c facing the circuit board 102. The receptacles 204 may also correspond to the through-holes 203 of the circuit board.

FIG. 2B is a side view of the assembly 100 in an assembled position with a partial cross-section, according to an embodiment of the invention. The components 104b and 104c may be mounted to the circuit board 102. The connector 202 of component 104b may be located within the through-hole 203 of the circuit board 102. Also, the receptacle 204 of component 104c may be located within the through-hole 203 of the circuit board 102 and may receive the connector 202 in a mated position. Also, in various embodiments, such as the embodiment shown in FIGS. 2B and 2C, the connectors and receptacles may not come in contact with the circuit board, thereby limiting any interference that the circuit board may otherwise have on the mating of the components. The area 206 of FIG. 2B is shown in a zoomed view in FIG. 2C.

FIG. 2C is a zoomed view of area 206 of FIG. 2B, according to an embodiment of the invention. This view shows a partial cross section of components 104b and 104c and the circuit board 102. The view also shows the connector 202 located within the through-hole 203 and mated with the receptacle 204. The connector 202 may be a cylindrical member and include a chamfered collar 208 located on the outer surface of the connector 202 and at the end of the connector 202 furthest from the component 104b. Other embodiments may have a connector of various shapes and sizes. For example, a connector may have plural flat sides such as a square, hexagon or any other similar shape. Other embodiments may have a collar 208 located at any other position along the length of the connector 202 other than the end of the connector 202 furthest from the component 104b. The receptacle 204 may be a hollow cylindrical member with one or more chamfered ridges 210 located on the inner surface of the receptacle 202. Other embodiments may have a receptacle of various shapes and sizes. For example, a receptacle may have plural flat sides such as a square, hexagon or any other similar shape. In various embodiments, a connector and a receptacle need not be the same shape so long as any difference in shape does not inhibit the mating of a connector and receptacle. The collar 208 may be chamfered in a direction opposite of the chamfering of the ridges 210 so that when the connector 202 and receptacle 204 are joined it may be relatively easier to insert the connector 202 into the receptacle 204 than it may be to separate them. The collar 208 of the connector 202 may be referred to as a type of pawl, and the ridges 210 of the receptacle 204 may be referred to as a type of linear ratchet. Other embodiments may have the location of the collar 208 and the ridges 210 reversed such that the collar 208 is located on the receptacle 204 and the ridges 210 are located on the connector 202. Other embodiments of the invention may include any suitable type of connector and receptacle other than those shown in FIG. 2C. For example, a connector may include a threaded fastener such as a screw or bolt while a corresponding receptacle may include a threaded aperture to receive the screw or bolt.

FIG. 2D is an alternative embodiment of FIG. 2C. In the shown embodiments, the receptacle 204 does not include a portion located within the through-hole 203. For example, the receptacle 204 may be an aperture in the component 104c. As in FIG. 2C, the ridges 210 may be located on the inner surface of the receptacle 204. The connector 202 may pass through the through-hole of the circuit board 102 in order to mate with the receptacle 204.

FIG. 2E is a top view of a connector 202, according to an embodiment of the invention. In the shown embodiment, the collar 208 or pawl may be located on only a portion of the outer circumference of the connector 202. The collar 208 shown in FIG. 2E includes two quarter sections where the collar 208 is present and two quarter sections where the collar 208 is not present, but in alternative embodiments the size and quantity of present and non-present sections may differ. The connector 202 may be fixed or it may be coupled to a component 104 in a way that allows the connector 202 to be rotated about its axis. For example, a connector may be accessible from the opposite side of a component on which it is located and may be rotated with the use of a tool such as a screwdriver. In other embodiments, a connector may have a portion that extends beyond the opposite side of a component and includes an element that facilitates manual rotation such as an appendage or tab.

FIG. 2F is a top view of a receptacle 204, according to an embodiment of the invention. In the shown embodiment, the ridges 210 or ratchet may be located on only a portion of the inner circumference of the receptacle 204. The ridges 210 shown in FIG. 2E includes two quarter sections where the ridges 210 are present and two quarter sections where the ridges 210 are not present, but in alternative embodiments the size and quantity of present and non-present sections may differ. The receptacle 204 may be fixed or it may be coupled to a component 104 in a way that allows the receptacle 204 to be rotated about its axis, similarly to the previously mentioned examples regarding the connector 202. The combination of the connector 202 of FIG. 2E and the receptacle 204 of FIG. 2F may allow the connector 202 and receptacle 204 to unlock by rotating either the connector 202 or receptacle 204 and thereby allow the components 104 to disconnect.

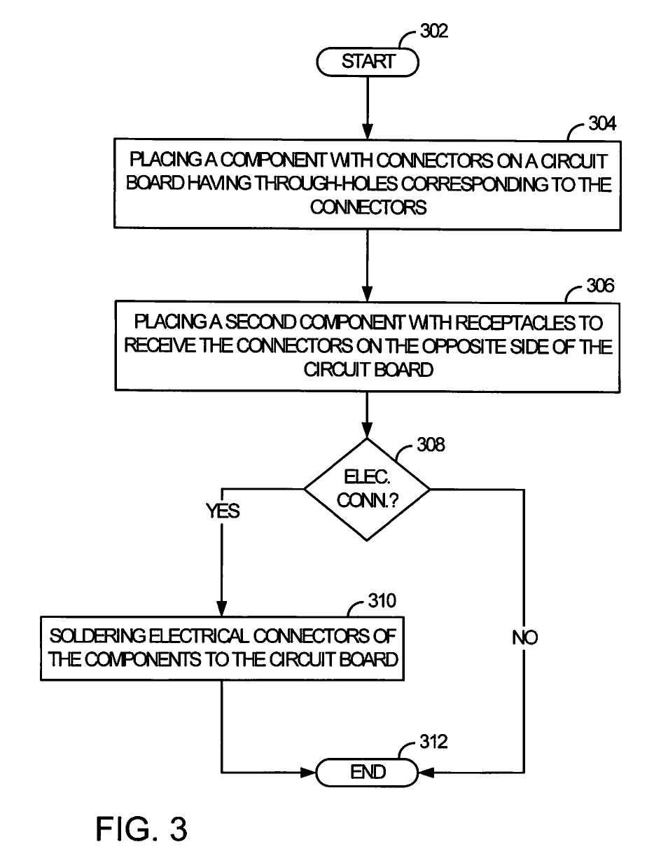

FIG. 3 is a flow chart of a method of securing opposing components to a circuit board, according to an embodiment of the invention. The process may begin at block 302. Block 304 may contain the operation of placing a component, such as a connector for an in-line memory module, on a circuit board. This component may have connectors corresponding to through-holes of the circuit board. When the component is placed on the circuit board the connectors may enter the through-holes of the circuit board. Block 306 may contain the operation of placing another component, such as a connector for an in-line memory module, on the side of the circuit board opposite the side where the first component was placed. This component may have receptacles for receiving the connectors when the receptacles and connectors are in a mated position. When the component is placed on the circuit board the receptacles mate with the connectors thereby securing both components to the circuit board.

Block 308 may contain a deciding operation that determines if one or more of the components are to be electronically connected to the circuit board. If one or more components are to be electronically connected to the circuit board, then one or more electrical connectors of the components is soldered to one or more electrical connectors of the circuit board. Upon completion of the operation of block 310, the operation may proceed to block 312 where the process may end. Returning to block 308, if there are no components that are to be electronically connected to the circuit board then the process moves to block 312 where the process may end.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An assembly comprising:
a first component having one or more connectors corresponding to one or more through-holes of a circuit board; and
a second component having one or more receptacles to fixedly receive the connectors, wherein the first and second components are adapted to be located on opposing sides of the circuit board in an assembled position.

2. The assembly of claim 1, wherein the first and second components have electrical connectors soldered to the circuit board.

3. The assembly of claim 1, wherein the connectors include one or more pawls and the receptacles include one or more ratchets.

4. The assembly of claim 3, wherein a pawl is located on a portion of the outer circumference of a connector.

5. The assembly of claim 4, wherein the connector is coupled to the first component in a manner that allows the connector to be rotated about its axis.

6. The assembly of claim 3, wherein a ratchet is located on a portion of the inner circumference of a receptacle.

7. The assembly of claim 6, wherein the receptacle is coupled to the second component in a manner that allows the receptacle to be rotated about its axis.

8. The assembly of claim 1, wherein the connectors are threaded members and the receptacles are threaded apertures.

9. An assembly to secure DIMM connectors to a circuit board comprising:
a first DIMM connector having one or more connectors corresponding to one or more through-holes of a circuit board; and
a second DIMM connector having one or more receptacles to fixedly receive the connectors, wherein the first and second DIMM connectors are adapted to be located on opposing sides of the circuit board in an assembled position.

10. The assembly of claim 9, wherein the first and second DIMM connectors have electrical connectors soldered to the circuit board.

11. The assembly of claim 9, wherein the connectors include one or more pawls and the receptacles include one or more ratchets.

12. The assembly of claim 11, wherein a pawl is located on a portion of the outer circumference of a connector.

13. The assembly of claim 12, wherein the connector is coupled to the first DIMM connector in a manner that allows the connector to be rotated about its axis.

14. The assembly of claim 11, wherein a ratchet is located on a portion of the inner circumference of a receptacle.

15. The assembly of claim 14, wherein the receptacle is coupled to the second DIMM connector in a manner that allows the receptacle to be rotated about its axis.

16. The assembly of claim 9, wherein the connectors are threaded members and the receptacles are threaded apertures.

17. A method comprising:
placing a first component having one or more connectors on a first side of a circuit board having one or more through-holes corresponding to the connectors; and
placing a second component having one or more receptacles to fixedly receive the connectors on a second side of the circuit board, wherein the first side of the circuit board and the second side of the circuit board are opposing sides.

18. The method of claim 17, further comprising soldering electrical connectors located on the first and second components to electrical connectors located on the circuit board.
